(19) United States
(12) Patent Application Publication
(10) Pub. No.: US 2009/0102357 A1
(43) Pub. Date: Apr. 23, 2009

(54) ORGANIC ELECTRO-LUMINESCENCE LIGHT-EMITTING DEVICE AND PROCESS FOR PRODUCING THE SAME

(75) Inventor: Tamami Koyama, Chiba (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Minato-ku, Tokyo (JP)

(21) Appl. No.: 11/916,566

(22) PCT Filed: Jun. 6, 2006
(86) PCT No.: PCT/JP2006/311705

§ 371 Date: Dec. 5, 2007

Related U.S. Application Data
(60) Provisional application No. 60/690,923, filed on Jun. 16, 2005.

(30) Foreign Application Priority Data
Jun. 7, 2005 (JP) 2005-167165

(51) Int. Cl. H01L 51/52; H01L 51/56; H01L 33/00

(52) U.S. Cl. 313/504; 438/29; 257/E33.061

(57) ABSTRACT

Disclosed is an organic EL light-emitting device having an organic light-emitting element including a transparent substrate having a transparent electrode (anode), a light-emitting compound layer containing a light-emitting compound and a cathode laminated thereon, and a sealing member for sealing the light-emitting element and shielding external air and an oxygen absorbing member, wherein oxygen is contained at an interface between the light-emitting compound layer and the cathode.

### CROSS REFERENCES OF RELATED APPLICATIONS

This application is an application filed under 35 U.S.C. §111(a) claiming benefit pursuant to 35 U.S.C. §119(e) (1) of the filing dates of Provisional Application 60/690,923 filed Jun. 16, 2005 pursuant to 35 U.S.C. §111(b).

### TECHNICAL FIELD

The present invention relates to organic electro-luminescence (hereinafter, also referred to as organic EL) light-emitting devices having excellent durability and rectification characteristic and to processes for producing the same. More specifically, the invention relates to organic phosphorescent devices and to a process for producing the same.

### BACKGROUND ART

Organic light-emitting elements using an organic substance are regarded as promising with respect to applications as low-cost large-area full-color display elements of a solid light-emitting type and write light source arrays and in recent years, are actively studied and developed. In general, an organic light-emitting element is constituted of a light-emitting compound layer containing a light-emitting layer and one pair of counter electrodes interposing the subject light-emitting compound layer therebetween. When a voltage is applied to such an organic light-emitting element, an electron is injected into the light-emitting compound layer from a cathode and a hole is injected into there from an anode. When the electron and the hole are recombined in the light-emitting layer and the energy level is returned from a conduction band to a valence band, the energy is released as light, thereby obtaining light emission.

Conventional organic light-emitting elements involve such a problem that the drive voltage is high and that the luminance brightness and luminous efficiency are low. In recent years, there are reported various technologies for solving this problem, and for example, an organic light-emitting element having an organic thin film formed by vapor deposition of an organic compound is known (see Applied Physics Letters, Vol. 51, page 913, 1987). This organic light-emitting element has a laminated double layer structure of an electron-transporting layer composed of an electron transport material and a hole-transporting layer composed of a hole transport material and exhibits a largely improved light-emitting characteristic as compared with a single-layered element. A low molecular amine compound is used as the hole transport material, an aluminum complex of 8-quinolinol (Alq) is used as the electron transport material/light-emitting material, and the luminescent color is green. Thereafter, there are also reported a number of organic light-emitting elements having a vapor deposited organic thin film (see references as described in Macromolecular Symposium, Vol. 125, page 1, 1997). However, such organic light-emitting elements are very low with respect to the luminous efficiency as compared with inorganic LED elements and fluorescent tubes. This matter is a serious problem in practical implementation.

Almost all of conventional organic light-emitting elements utilize fluorescence emission obtainable from a singlet exciton of an organic light-emitting material. In the simple mechanism of quantum chemistry, in the exciton state, a ratio of a single exciton from which fluorescence emission is obtained to a triplet exciton from which phosphorescent light emission is obtained is 1:3. That is, so far as the fluorescence emission is utilized, only 25% of the exciton can be efficiently conjugated so that the luminous efficiency of the fluorescent element is low. Under such circumstances, phosphorescent elements using a phenylpyridine complex of iridium were recently reported (see, for example, Applied Physics Letters, Vol. 75, page 4, 1999 and Japanese Journal of Applied Physics, Vol. 38, page L1502, 1999). These phosphorescent elements exhibit a luminous efficiency of from 2 to 3 folds as compared with conventional fluorescent elements. However, the luminous efficiency is lower than a theoretical luminous efficiency limit, and a more improvement in the luminous efficiency is demanded for achieving practical implementation. Furthermore, in comparison with conventional fluorescent elements, the durability of the subject phosphorescent elements is inferior, and its improvement is eagerly desired. As a measure for improving the durability of phosphorescent elements, there is designed a measure for reducing the concentration of oxygen within an organic EL light-emitting device.

JP-A-2002-175882

This document is concerned with an invention which has been made on the basis of finding that a phosphorescent element utilizing a triplet exciton is different from a fluorescent element utilizing a singlet exciton and is liable to cause extinction due to oxygen. However, judging from a gist of this invention, it could be said that the invention is more focused especially on the nature of a light-emitting material rather than an improvement of characteristics of the entire element. On the other hand, from the viewpoint of improving the drive life as an element, there have been made various inventions. In particular, with respect to the fluorescent element, it is reported that a large improvement in the performance is achieved by positively using oxygen.

JP-A-2002-198187

According to this document, by positively exposing a cathode under an oxygen atmosphere at the time of forming a first cathode of an organic EL light-emitting device, a defect of the interfacial level present at the interface can be covered so that a complete interface is formed, thereby inhibiting an increase of the leak current. However, it was thought that this measure couldn't be applied directly to an organic light-emitting element containing a phosphorescent high molecular compound which is very weak against oxygen as described therein.

Patent Document 1: JP-A-2002-175882

Patent Document 2: JP-A-2002-198187

### DISCLOSURE OF THE INVENTION

An object of the invention is to provide a light-emitting device which has excellent luminance brightness, luminous efficiency and durability and can be effectively utilized for surface light sources of, for example, full-color displays, backlights and illumination light sources, light source arrays such as printers, and so on and a process for producing the same.

In order to solve the foregoing problems, the present inventors made intensive investigations. As a result, they have discovered a production process in which nonetheless the fact that a phosphorescent element utilizing a triplet exciton is different from a fluorescent element utilizing a singlet exciton in respect of being liable to be affected by oxygen, thereby causing an extinction phenomenon due to oxygen, for the purpose of improving a rectification characteristic of the element, a measure that containing oxygen in a cathode layer coming into contact with an organic EL light-emitting layer is applicable and found that a phosphorescent element having excellent light-emitting characteristic and durability is obtained, leading to accomplishment of the invention. That is, according to G. D. Marco, et al. (Adv. Mater. 1996, 8 (7), page 576), an extinction effect of a phosphorescent dye doped on a high molecular compound thin film due to oxygen is about 18% in a concentration of oxygen of 20% and is reversible. By utilizing this nature and using a delayed oxygen adsorbing agent in combination, in an organic EL light-emitting device, it has become possible to stabilize an interface between a cathode and a light-emitting layer by diffusing oxygen into a first cathode in a high concentration of oxygen and subsequently remove the excessive oxygen. That is, it has become possible to design to stabilize the cathode without hindering the nature of a phosphorescent material.

Specifically, the invention (I) is concerned with an organic EL light-emitting device having an organic light-emitting element comprising a transparent substrate having a transparent electrode (anode), a light-emitting compound layer comprising a light-emitting compound and a cathode laminated thereon, and a sealing member for sealing the light-emitting element and shielding external air and an oxygen absorbing member, wherein oxygen is contained at an interface between the light-emitting compound layer and the cathode and with a process for producing the same.

The invention (II) is concerned with an organic EL light-emitting device of the invention (I), wherein the light-emitting compound layer comprises a phosphorescent high molecular material and with a process for producing the same.

The invention (III) is concerned with an organic EL light-emitting device of the invention (I), wherein the light-emitting compound layer comprises a fluorescent high molecular material and with a process for producing the same.

Specifically, the invention is concerned with organic EL light-emitting devices, a process for producing the same, and a surface emitting light source, a backlight for display devices, etc., a display device, an illumination device, an interior or an exterior using such an organic EL light-emitting device as described hereunder.

In addition, for example, the invention is concerned with the following matters.

[1] An organic EL light-emitting device having an organic light-emitting element comprising a transparent substrate having a transparent electrode (anode), a light-emitting compound layer containing a light-emitting compound and a cathode laminated thereon, and a sealing member for sealing the light-emitting element and shielding external air and an oxygen absorbing member, wherein oxygen is contained at an interface between the light-emitting compound layer and the cathode.
[2] An organic EL light-emitting device having an organic light-emitting element comprising a transparent substrate having a transparent electrode (anode), a light-emitting compound layer containing a light-emitting compound and a cathode laminated thereon, and a sealing member for sealing the light-emitting element and shielding external air and an oxygen absorbing member, wherein the cathode comprises a first cathode and a second cathode, and oxygen is contained at an interface between the light-emitting compound layer and the first cathode.
[3] An organic EL light-emitting device as described in [2], wherein the first cathode and the second cathode are laminated.
[4] An organic EL light-emitting device having an organic light-emitting element comprising a transparent substrate having a transparent electrode (anode), a light-emitting compound layer containing a light-emitting compound and a cathode laminated thereon, and a sealing member for sealing the light-emitting element and shielding external air and an oxygen absorbing member, wherein the cathode comprises plural layers, and the content of oxygen in a first cathode of the plural cathodes, said first cathode coming into contact with the light-emitting compound layer, is higher than the content of oxygen in a cathode on and after the second cathode not coming into contact with the light-emitting compound layer.
[5] An organic EL light-emitting device as described in any one of [1] to [4], wherein the cathode has a film thickness of from 20 to 200 nm.
[6] An organic EL light-emitting device having an organic light-emitting element comprising a transparent substrate having a transparent electrode (anode), a light-emitting compound layer containing a light-emitting compound and a cathode laminated thereon, and a sealing member for sealing the light-emitting element and shielding external air and an oxygen absorbing member as described in any one of [1] to [5], wherein an oxygen absorbing member is present in a gap between the sealing member and the organic light-emitting element.
[7] A process for producing an organic EL light-emitting device as described in any one of [1] to [6], which comprises forming the cathode in a film thickness of from 20 to 200 nm.
[8] A process for producing an organic EL light-emitting device having an organic light-emitting element comprising a transparent substrate having a transparent electrode (anode), a light-emitting compound layer containing a light-emitting compound and a cathode laminated thereon, and a sealing member for sealing the light-emitting element and shielding external air and an oxygen absorbing member as described in [6], wherein oxygen of a prescribed concentration is incorporated into the organic light-emitting device at the time of sealing.
[9] A process for producing an organic EL light-emitting device as described in any one of [1] to [6], wherein the concentration of oxygen in the organic EL light-emitting device at the time of sealing falls within the range of from 1,000 to 5,000 ppm, and the concentration of oxygen in the organic light-emitting device after from 10 to 50 hours after sealing is not more than 100 ppm.
[10] A process for producing an organic EL light-emitting device as described in [9], wherein the oxygen absorbing member which absorbs oxygen in the organic EL light-emitting device at the time of sealing starts to absorb oxygen step by step after sealing, thereby regulating the concentration of oxygen in the organic EL light-emitting device at not more than 100 ppm within 50 hours.
[11] A process for producing an organic EL light-emitting device as described in any one of [7] to [10], wherein the light-emitting compound layer contains a phosphorescent high molecular material.
[12] A process for producing an organic EL light-emitting device as described in any one of [7] to [10], wherein the light-emitting compound layer contains a fluorescent high molecular material.
[13] An organic EL light-emitting device as produced by a production process as described in any one of [7] to [12].
[14] A surface emitting light source, a backlight for display devices, a display device, an illumination device, an interior or an exterior using an organic EL light-emitting device as described in any one of [1] to [6] and [13].

### EFFECT OF THE INVENTION

By using the process for producing an organic EL light-emitting device according to the invention (I), it is possible to produce an organic EL light-emitting device having excellent durability and rectification characteristic.

### BRIEF DESCRIPTION OF THE DRAWINGS

FIG. 1 is a schematic cross-sectional view to show an embodiment of the organic EL light-emitting device of the invention.

FIG. 2 is a schematic cross-sectional view to show an embodiment of the organic EL light-emitting device of the invention.

FIG. 3 is a schematic cross-sectional view to show an embodiment of the organic EL light-emitting device of the invention.

FIG. 4 is a schematic cross-sectional view to show an embodiment of the organic EL light-emitting device of the invention.

FIG. 5 is a graph to show a rectification characteristic of the organic EL light-emitting device of the invention.

FIG. 6 is a graph to show a rectification characteristic of the organic EL light-emitting device of the invention.

1: Transparent substrate
2: Transparent electrode (anode)
3: Light-emitting compound layer
4: Cathode
5: Anode lead
6: Cathode lead
7: Organic light-emitting element
8: Sealant (adhesive)
9: Sealing member
10: Gap
11: Hole-transporting layer
12: Light-emitting layer
13: Electron-transporting layer

### BEST MODE FOR CARRYING OUT THE INVENTION

The invention will be hereunder described in detail.

The light-emitting element of the invention relates to an organic EL light-emitting device having an organic light-emitting element comprising a transparent substrate having a transparent electrode (anode), at least one light-emitting compound layer and a cathode laminated thereon, and a sealing member for sealing the organic light-emitting element and to an organic EL light-emitting device having an oxygen absorbing member within the device. The light-emitting compound layer contains a light-emitting material, and the light-emitting material contains a phosphorescent compound. As the need arises, a light-emitting compound layer other than the light-emitting layer, a protective layer, and so on may be provided. This organic EL light-emitting device can be produced by the production process of the invention. In the subject production process, a sealing step for setting up the sealing member and the oxygen absorbing member within the organic EL light-emitting device is carried out under an atmosphere having a concentration of oxygen of from 100 to 5,000 ppm.

Incidentally, the “oxygen absorbing member” may be often called “oxygen absorber” in this specification.

In this way, oxygen is diffused in a first cathode within 50 hours after sealing so that a level of impurities as generated on the first cathode can be dissolved. An object of the treatment in this stage is to thoroughly disperse oxygen on the first electrode. Accordingly, for the purpose of improving the dispersion efficiency, a low current may be made to flow through the element, or heat may be applied to the element. After a lapse of a certain period of time for achieving the dispersion of oxygen on the first cathode, excessive oxygen is present within the organic EL light-emitting device. For the purpose of adsorbing this excessive oxygen and oxygen or water which comes into the organic EL light-emitting device from the air outside the organic EL light-emitting device, it is required that the oxygen absorbing member within the organic EL light-emitting device functions. Though the time for thoroughly dispersing oxygen on the first cathode varies depending upon the structure of the element, it is from several minutes to several tens hours. Accordingly, it is desired that the oxygen absorbing member starts to function after several minutes to several tens hours after sealing.

By this measure, it is possible to cover a defective site which is present on the first cathode and stably drive the element. Besides, it is possible to reduce the amount of oxygen which is thereafter absorbed in the light-emitting layer, whereby the oxygen which has already been absorbed in the light-emitting layer is also absorbed in the oxygen absorbing member step by step. Furthermore, the amount of an oxygen gas which comes into the sealed light-emitting element from the outside air is reduced. As a result, it is possible to inhibit the disappearance of a triplet exciton which is very sensitive to the oxygen gas, thereby obtaining a light-emitting element exhibiting high durability and rectification characteristic.

It is required that the concentration of oxygen within the organic EL light-emitting device is finally not more than 100 ppm, and preferably not more than 50 ppm. Examples of an inert gas for sealing which is used for the purpose of adjusting the concentration of oxygen include nitrogen and argon.

As the sealing member, a sealing cap, a sealing cover, and the like can be used. As a material which constitutes the sealing member, materials having low water permeability and oxygen permeability may be employed. Specific examples thereof include inorganic materials such as glass and ceramics; metals such as stainless steel, iron, and aluminum; polyesters such as polyethylene terephthalate, polybutylene terephthalate, and polyethylene naphthalate; and high molecular materials such as polystyrene, polycarbonates, polyethersulfones, polyallylates, allyl diglycol carbonate, polyimides, polycycloolefins, norbornene resins, poly-(chlorotrifluoroethylene), TEFLON (a registered trademark), and polytetrafluoroethylene-polyethylene copolymers. Above all, high molecular materials are preferable for the purpose of forming a flexible light-emitting element or a coating type light-emitting element,

In setting up the sealing member in the organic light-emitting element, a sealant (adhesive) may be properly used. As the sealant, ultraviolet light curable resins, thermosetting resins, two-pack curable resins, water curable resins, anaerobic curable resins, hot melt type resins, and so forth can be used.

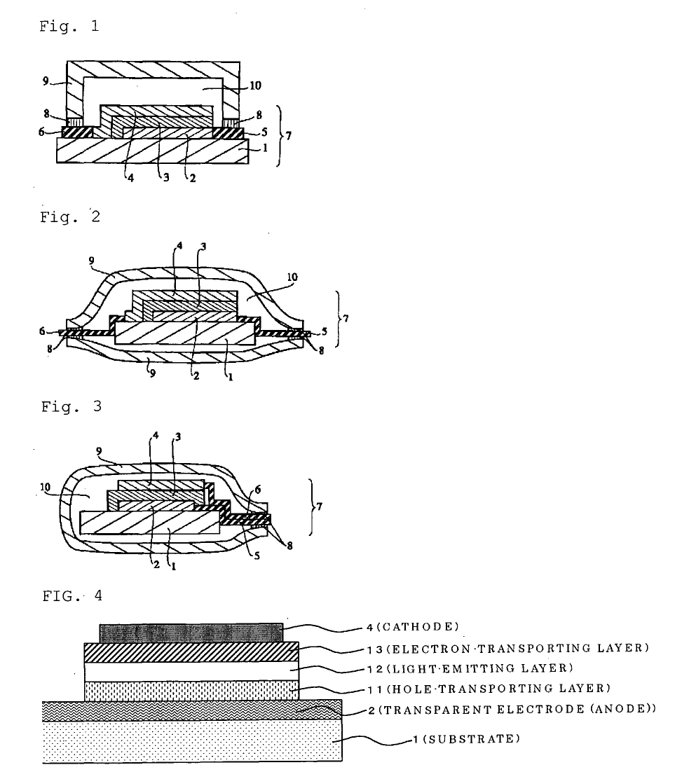

Each of FIGS. 1 to 3 shows a schematic cross-sectional view to show an embodiment of the light-emitting element of the invention. Each of light-emitting elements as illustrated in FIGS. 1 to 3 has an organic light-emitting element 7 comprising a transparent substrate 1 having a transparent electrode (anode) 2, a light-emitting compound layer 3 and a cathode 4 laminated thereon, and a sealing member 9 for sealing the light-emitting compound layer 3. In these embodiments, the sealing member 9 is adhered to the transparent substrate 1, an anode lead 5, a cathode lead 6, and so on by a sealant (adhesive) 8 and set up on the organic light-emitting element 7. In the invention, the sealing member 9 may be set up only in the side of the cathode 4 as illustrated in FIG. 1, too. Alternatively, the whole of the organic light-emitting element 7 may also be covered by the sealing member 9 as illustrated in FIGS. 2 and 3. So far as the light-emitting compound layer 3 can be sealed and the outside air can be shielded, the sealing member 9 is not particularly limited with respect to the shape, size and thickness, etc. Furthermore, in the case of covering the whole of the organic light-emitting element 7 by the sealing member 9 as in the light-emitting elements as illustrated in FIGS. 2 and 3, the sealing members 9 may be thermally fused to each other without using the sealant 8. A gap 10 may exist between the sealing member 9 and the organic light-emitting element 7 as the need arises. A water absorbing agent or an inert liquid may be inserted in the gap 10. In addition, in the invention, a slow-acting material is especially useful as the oxygen absorbing member.

Examples of the oxygen absorbing member include the following oxygen absorbing resin compositions.

### (Oxygen Absorbing Resin Composition)

The oxygen absorbing resin composition which can be used in the invention is made of a resin composition containing an oxygen reactive thermoplastic resin and a transition metal catalyst. As the oxygen reactive thermoplastic resin, a single kind of a thermoplastic resin or a mixture of two or more kinds of thermoplastic resins is used. In particular, organic high molecular compounds containing a hydrogen atom bound to a tertiary carbon atom can be preferably used. Examples thereof include polystyrene, polybutene, polyvinyl alcohol, polyacrylic acid, polymethylacrylate, polyacrylamide, polyacrylonitrile, polyvinylacetate, polyvinyl chloride, polyvinyl fluoride, ethylenevinyl acetate copolymers, ethyleneethyl acrylate copolymers, ethyleneacrylic acid copolymers, ethylene-methyl acrylate copolymers, acrylic rubbers, polymethylpentene, polypropylene, ethylene-propylene rubbers, ethylene-1-butene rubbers, butyl rubbers, and hydrogenated styrene-butadiene rubbers. Of these, hydrogenated styrenebutadiene rubbers are preferable.

The hydrogenated styrene-butadiene rubber which is preferably used in the invention is a copolymer containing, as constitutional units, a styrene unit (—CH₂—CH(C₆H₅)—) and a hydrogenated butadiene unit (—CH₂—CH₂—CH₂—CH₂— or —CH₂—CH(C₂H₅)—). The configuration of the styrene unit and the hydrogenated butadiene unit may be alternate, random or block. This hydrogenated styrene-butadiene rubber is obtained by a hydrogenation reaction of a styrene-butadiene rubber to a degree that an aliphatic carbon-carbon double bond of the butadiene unit does not substantially exist.

In the case of using a hydrogenated styrenebutadiene rubber as the oxygen reactive thermoplastic resin, a proportion of the hydrogenated styrenebutadiene rubber is selected within the range of from 10 to 100% by weight. In view of oxygen absorption performance, physical strength and economy, this proportion is preferably from 10 to 60% by weight in the resin composition.

In the case of using a mixture of two or more kinds of thermoplastic resins as the oxygen reactive thermoplastic resin, it is preferable that oxygen reactive thermoplastic resin domains have a mutually finely dispersed micro structure each other. For example, the hydrogenated styrene-butadiene rubber is preferable because it has a nature such that when kneaded with a polyolefin based resin such as polypropylene resins, it is ultra-finely dispersed in a size of not more than about 100 nm.

The transition metal catalyst is a transition metal compound such as salts or oxides of a transition element metal. As metal species of the transition metal catalyst, manganese, iron, cobalt, nickel, and copper are suitable. Of these, manganese, iron and cobalt are especially suitable because they have an excellent catalytic action. The metal salt of a transition element metal includes mineral acid salts or fatty acid salts of a transition element metal. Examples thereof are hydrochloric acid salts, sulfuric acid salts, nitric acid salts, acetic acid salts or higher fatty acid salts of a transition element metal.

In view of easiness of handling, the transition metal catalyst is preferably a supported catalyst having a transition element metal salt supported on a carrier. Though the kind of the carrier is not particularly limited, zeolite, diatomaceous earth, calcium silicates, and so on can be used. In particular, a carrier whose size is about 100 μm at the time of or after preparing a catalyst and when dispersed in the resin, becomes not more than 380 nm is preferable because it is satisfactory with respect to handling properties and when blended with the resin, gives a transparent resin composition. As such a carrier, synthetic calcium silicate based compounds are preferable. A proportion of the transition metal catalyst is preferably from 0.001 to 10% by weight, and especially preferably from 0.01 to 1% by weight in terms of a metal atom weight in the oxygen absorbing resin composition in view of oxygen absorption performance, physical strength and economy of the oxygen absorbing resin composition.

The oxygen absorbing resin composition is obtained by heating and kneading a thermoplastic resin and a transition metal catalyst together with other thermoplastic resin in the presence of oxygen. For example, the oxygen absorbing resin composition can be produced by kneading a mixture of a hydrogenated styrene-butadiene rubber and polypropylene together with a transition metal catalyst using an extruder while introducing the outside air by a vacuum pump.

Any apparatus for undergoing kneading of the resin composition is employable so far as it is able to mix the composition in a molten state while accepting feed of oxygen, and examples thereof include a single-screw extruder, a twin-screw extruder, and a laboplast mill. Examples of a method for feeding oxygen during kneading include a method of operating a laboplast mill in the presence of an oxygen-containing gas and a method of installing an exhaust pump in an extruder and sucking an oxygen-containing gas by evacuation. The resin composition can be produced on an industrial scale by melting and kneading a thermoplastic resin and a transition metal catalyst using a single-screw or twin-screw extruder installed with a vacuum pump while introducing the outside air by the vacuum pump. Examples of the oxygen-containing gas which is utilized include pure oxygen, air, and a mixed gas of oxygen and an inert gas. Of these, air is preferable.

The oxygen absorbing resin composition contains a radical having a g value of the electron spin resonance (ESR) measurement in the range of 2.000 to 2.010 in an amount of 1×10⁻⁷ moles/g or more, and preferably 5×10⁻⁷ moles/g or more. Though there is no upper limit with respect to the content of radical, it is usually not more than 1×10⁻⁴ moles/g. It is meant by the terms “1×10⁻⁷ moles/g” as referred to herein that 1×10⁻⁷×6×10²³ (spins) radicals are contained per gram of the oxygen absorbing resin composition. It is estimated from the g value of ESR that the radical contained in the oxygen absorbing resin composition of the invention is an oxygen-containing organic radical, namely an alkoxy radical (RO.), an alkyl peroxy radical (ROO.), or a mixture thereof.

The fact that the oxygen-containing organic radical which is contained in the oxygen absorbing resin composition is stably present at room temperature is confirmed by the electron spin resonance (ESR) measurement. With respect to this matter, it is estimated that the oxygen-containing organic radical is stabilized because its transfer in the oxygen absorbing resin composition is controlled, thereby bringing an effect for shortening the induction period until the oxygen absorption reaction is started.

The oxygen absorbing resin composition has a characteristic feature that its own induction period until the oxygen absorption is started is short. However, it is possible to further shorten the induction period by exposure with ultraviolet light.

Other thermoplastic resin with which the hydrogenated styrene-butadiene rubber and the transition metal catalyst are blended is a resin which is softened by heating to have such plasticity that it is moldable. Examples thereof include polyolefins such as polyethylene and polypropylene, poly-chlorinated resins such as polyvinyl chloride and polyvinylidene chloride, aromatic hydrocarbon resins such as polystyrene, polyesters such as polyethylene terephthalate, polyamides such as nylon 6 and nylon 66, and resin compositions containing at least one kind thereof.

A proportion of the hydrogenated styrene-butadiene rubber in the oxygen absorbing resin composition is selected within the range of from 10 to 100% by weight. It is preferably from 10 to 60% by weight in the oxygen absorbing resin composition in view of oxygen absorption performance, physical strength and economy. A proportion of the transition metal catalyst is preferably from 0.001 to 10% by weight, and especially preferably from 0.01 to 1% by weight in terms of a metal atom weight in the composition in view of oxygen absorption performance, physical strength and economy.

Another constitution of the oxygen absorbing resin composition is a resin composition resulting from further blending a resin composition comprising an oxygen reactive thermoplastic resin and a transition metal catalyst in other thermoplastic resin. It is preferable that the oxygen absorbing resin composition has a micro structure in which an oxygen reactive thermoplastic resin domain is dispersed in other thermoplastic resin domain.

Such an oxygen absorbing resin composition can be produced by further kneading a resin composition obtained by heating and kneading an oxygen reactive thermoplastic resin and a transition metal catalyst in the presence of oxygen together with other thermoplastic resin using an extruder.

The oxygen absorbing resin composition can be converted into a composition having both an oxygen absorbing function and a drying function and/or a gas adsorbing function by mixing under heating at least one kind selected from a drying agent and a gas adsorbing agent.

As the drying agent, a drying agent capable of not only chemically adsorbing water but also keeping a solid state even after adsorbing water. Examples thereof include alkaline earth metal oxides such as MgO, CaO, and BaO; sulfates such as Na₂SO₄, MgSO₄, and CaSO₄; and alkaline earth metals such as Ca and Ba. By adding the drying agent in the oxygen absorbing resin composition, a resin composition having both an oxygen absorbing function and a drying function is obtained.

As the gas adsorbing agent, synthetic zeolites such as ZEOLITE 5A, ZEOLITE Y, and ZEOLITE 13X; natural zeolites such as mordenite, erionite, and faujasite; active carbons produced from various raw materials; and so on can be utilized. By adding the gas adsorbing agent in the oxygen absorbing resin composition, a resin composition having both an oxygen absorbing function and a gas adsorbing function is obtained. Both the drying agent and the gas adsorbing agent may be added in the oxygen absorbing resin composition. In this way, a resin composition having all of an oxygen absorbing function, a drying function and a gas adsorbing function is obtained.

The particle size of the drying agent and the gas adsorbing agent is not particularly limited so far as it does not bring a hindrance at the time of molding the resin composition. The use of a drying agent or a gas adsorbing agent having a particle size of not more than 100 nm is preferable because it is possible to obtain a transparent resin composition having all of an oxygen absorbing function, a drying function and a gas adsorbing function.

The oxygen absorbing resin composition is able to absorb oxygen of 100 mL/g or more per gram.

The oxygen absorbing resin composition may possibly have an induction period until oxygen absorbing activity is revealed in air. This induction period is relatively short, and an oxygen absorption rate after the induction period is high. It is also possible to further shorten the induction period by UV irradiation.

Since the oxygen absorbing resin composition uses an oxygen reactive thermoplastic resin as a component to be oxidized, it can satisfactorily achieve the oxygen absorption in a dried state having a relative humidity of not more than 70%, especially from 0 to 55%, and further from 0 to 40%.

In particular, in commercially available iron based oxygen scavengers and ascorbic acid based oxygen scavengers, the oxygen absorbing activity is generally lowered in a dried state. On the other hand, the matter that the oxygen absorbing resin composition which is used in the invention exhibits oxygen absorbing activity in a dried state is a conspicuous characteristic feature. Accordingly, an oxygen absorbing film containing the oxygen absorbing resin composition which is used in the invention is suitable for the removal of oxygen in the inside of an organic EL element in which a dried state is required.

### (Oxygen Absorbing Film)

The foregoing oxygen absorbing resin composition is molded into an oxygen absorbing film. As a film molding method, known measures such as a hot press method, a melt extrusion method, and a calender method can be applied. For the purpose of improving characteristics, stretching processing such as uniaxial stretching and biaxial stretching can also be applied. In view of mechanical physical properties and oxygen absorbing activity, a thickness of the oxygen absorbing film is preferably not more than 300 μm, and more preferably from 10 to 200 μm.

The oxygen absorbing film may be formed into a multilayered film by further laminating other film thereon.

For example, the oxygen absorbing film can also be formed into a multilayered film having both an oxygen absorbing function and a drying function and/or a gas adsorbing function by laminating a resin composition film containing the foregoing drying agent and/or gas adsorbing agent thereon.

As a resin composition which constitutes a hygroscopic layer or a gas adsorbing layer, a composition resulting from dispersing the foregoing drying agent or gas adsorbing agent in a thermally fusible resin such as polyolefins such as polyethylene and polypropylene, polychlorinated resins such as polyvinyl chloride and polyvinylidene chloride, ethylene-vinyl acetate copolymers, polystyrene, and polyethylene terephthalate can be used. Though the configuration of layers to be laminated is not particularly limited, an order of the hygroscopic layer, the gas adsorbing layer and the oxygen absorbing layer from the side opposing to the light-emitting structure is preferable.

The oxygen absorbing film can also be formed into an oxygen absorbing multilayered film which does not require a cabinet, etc. by laminating a gas barrier film thereon. For example, the oxygen absorbing film can be formed into a multilayered film by laminating a thermally fusible thermoplastic resin in one side of a layer made of the foregoing oxygen absorbing resin composition and a resin, a metal or a metal oxide having low oxygen permeability as a gas barrier layer in the other side thereof, respectively. Such an oxygen absorbing multilayered film is fixed on the light-emitting structure such that the gas barrier layer side is the side coming into contact with the outside air.

As the need arises, an interlaminar strength can also be enhanced by interposing a layer made of a thermoplastic resin having both high gas permeability and thermal fusibility enumerated by polyethylene, polypropylene, and polymethylpentene between the respective layers. By selecting materials to be used, it is also possible to form a transparent oxygen absorbing multilayered film in which the oxygen absorbing resin composition layer, the thermoplastic resin layer and the gas barrier layer are all made of a transparent layer. A thickness of the oxygen absorbing multilayered film is preferably not more than 300 μm, and more preferably from 10 to 200 μm.

As a process for producing the oxygen absorbing multilayered film, known laminating methods such as dry lamination and extrusion lamination can be applied.

The anode is formed of a conductive and light-permeable layer represented by ITO. In the case of observing organic light emission through the substrate, light permeability of the anode is essential. However, in the case of utility of observing organic light emission by top emission, namely through an upper electrode, the permeability of the anode is not required. An appropriate arbitrary material such as metals and metal oxides having a work function higher than 4.1 eV can be used as the anode. For example, gold, nickel, manganese, iridium, molybdenum, palladium, platinum, and so on can be used singly or in combination. The anode can also be selected from the group consisting of metal oxides, nitrides, selenides and sulfides. A substance resulting from film formation of the foregoing metal as a thin film of from 1 to 3 nm on the surface of ITO having good light permeability such that the light permeability is not hindered can also be used as the anode. As a film formation method on the surface of such an anode material, an electron beam vapor deposition method, a sputtering method, a chemical reaction method, a coating method, a vacuum vapor deposition method, and so on can be employed. A thickness of the anode is preferably from 2 to 300 nm.

### <<Element Constitution>>

The constitution of the organic light-emitting element of the invention is not limited to an example as illustrated in FIG. 4. Examples of an element constitution of layers which are successively provided between the anode and the cathode include (1) anode buffer layer/hole-transporting layer/light-emitting layer; (2) anode buffer layer/light-emitting layer/electron-transporting layer; (3) anode buffer layer/hole-transporting layer/light-emitting layer/electron-transporting layer; (4) anode buffer layer/layer containing a hole transport material, a light-emitting material and an electron transport material; (5) anode buffer layer/layer containing a hole transport material and a light-emitting material; (6) anode buffer layer/layer containing a light-emitting material and an electron transport material; (7) anode buffer layer/layer containing a hole electron transport material and a light-emitting material; and (8) anode buffer layer/light-emitting layer/hole block layer/electron-transporting layer. Furthermore, though the light-emitting layer as illustrated in FIG. 4 is a single layer, two or more light-emitting layers may be provided. In addition, the layer containing a hole transport material may be brought into direct contact with the surface of the anode without using the anode buffer layer.

Incidentally, in this specification, unless otherwise indicated, a compound and a layer made of all or at least one kind of an electron transport material, a hole transport material and a light-emitting material are called a light-emitting compound and a light-emitting compound layer, respectively.

By preliminarily treating the surface of the anode at the time of film formation of the anode buffer layer or the layer containing a hole transport material, the performance of a layer to be subjected to overcoating (for example, adhesion to the anode substrate, surface smoothness, and lowering of hole injecting barrier) can be improved. Examples of the preliminary treatment method include not only a high frequency plasma treatment but also a sputtering treatment, a corona discharge treatment, a UV ozone irradiation treatment, and an oxygen plasma treatment.

In the case where the anode buffer layer is prepared by coating by a wet process, the film formation can be carried out using a coating method such as a spin coating method, a casting method, a micro gravure coating method, a gravure coating method, a bar coating method, a roll coating method, a wire bar coating method, a dip coating method, a spray coating method, a screen printing method, a flexographic method, an offset printing method, and an inkjet printing method.

A compound which can be used for the film formation by the foregoing wet process is not particularly limited so far as it is a compound having good adhesiveness to the surface of the anode and the light-emitting compound which is contained in an upper layer thereof. It is more preferred to apply an anode buffer which has been generally used so far. Examples thereof include conductive polymers such as PEDOT which is a mixture of poly(3,4-ethylenedioxythiophene) and a polystyrenesulfonic acid salt and PANI which is a mixture of polyaniline and a polystyrenesulfonic acid salt. In addition, mixtures resulting from adding an organic solvent such as toluene and isopropyl alcohol in such a conductive polymer may be used. Also, conductive polymers containing a third component such as surfactants are useful. As the surfactant, a surfactant containing one group selected from the group consisting of an alkyl group, an alkylaryl group, a fluoroalkyl group, an alkylsiloxane group, a sulfuric acid salt, a sulfonic acid salt, a carboxylate, an amide, a betaine structure, and a quaternary ammonium group is used. A fluoride based nonionic surfactant is also useful.

In the organic light-emitting element of the invention, as the compounds which are used in the light-emitting compound layer, namely the light-emitting layer, the hole-transporting layer, and the electron-transporting layer, all of low molecular compounds and high molecular compounds can be used.

As the light-emitting material capable of forming the light-emitting layer of the organic light-emitting element of the invention, low molecular light-emitting materials and high molecular light-emitting materials as described in Yutaka OHMORI, OYO BUTURI, Vol. 70, No. 12, pp. 1419-1425 (2001) can be enumerated. Above all, high molecular light-emitting materials are preferable in view of the matter that the element preparation process is made simple, and phosphorescent materials are preferable in view of high luminous efficiency. In consequence, phosphorescent high molecular compounds are especially preferable.

In the organic light-emitting element of the invention, the light-emitting layer contains at least one phosphorescent high molecular compound containing a phosphorescent unit capable of phosphorescence emission and a carrier transport unit capable of transporting a carrier in one molecule thereof. The phosphorescent high molecular compound is obtained by copolymerizing a polymerizable substituent-containing phosphorescent compound and a polymerizable substituent-containing carrier transport compound. The phosphorescent compound is a metal complex containing one metal element selected from iridium, platinum, and gold. Above all, iridium complexes are preferable.

As the polymerizable substituent-containing phosphorescent compound, compounds resulting from substituting at least one hydrogen atom of each of metal complexes represented by the following formulae (E-1) to (E-42) with a polymerizable substituent can be enumerated.

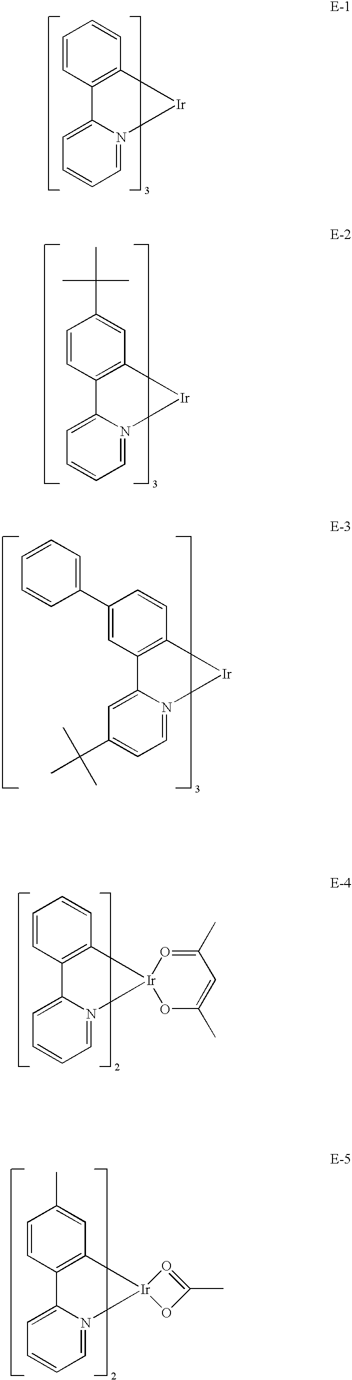

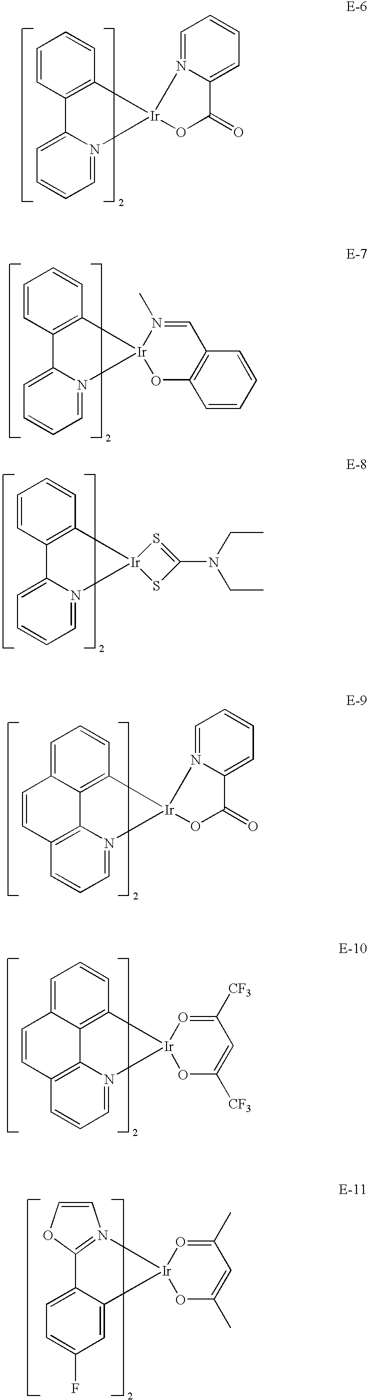

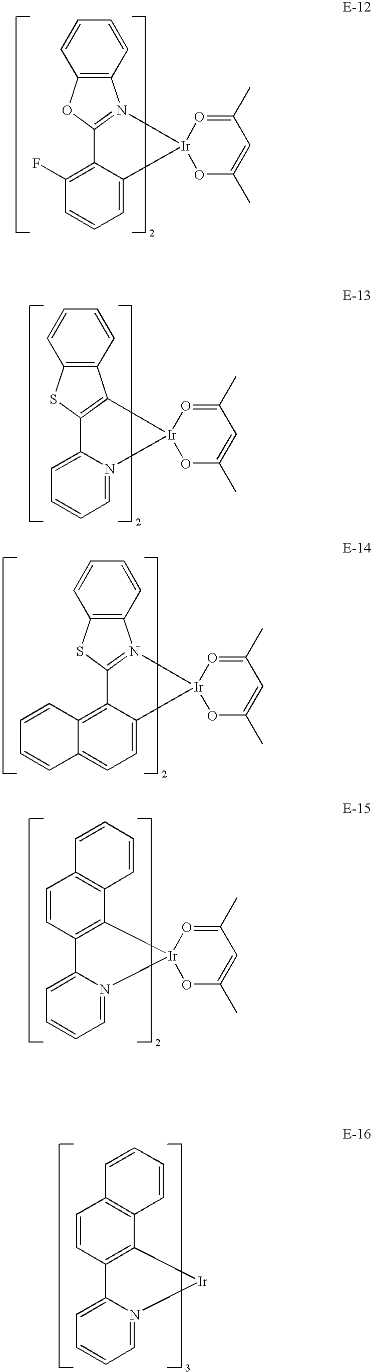

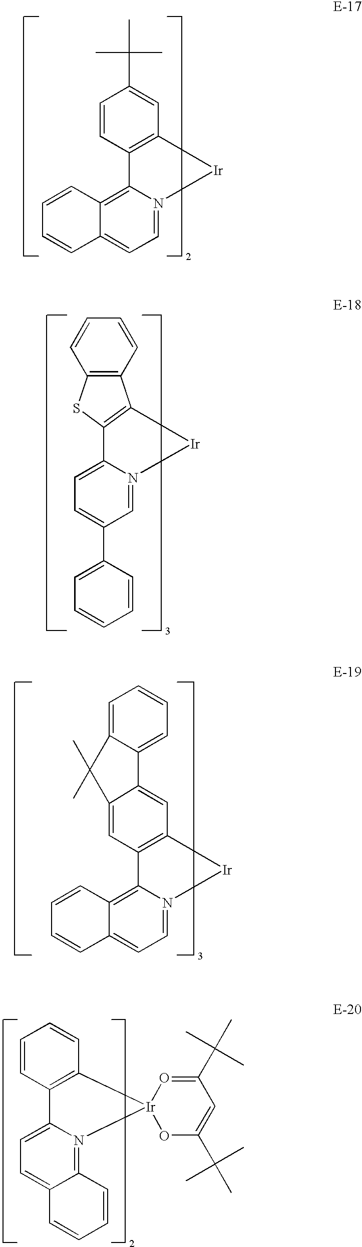

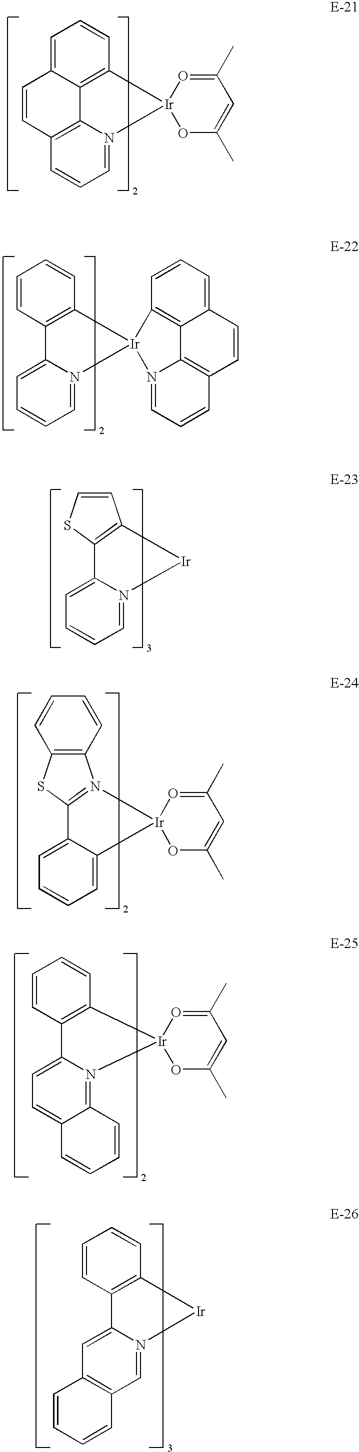

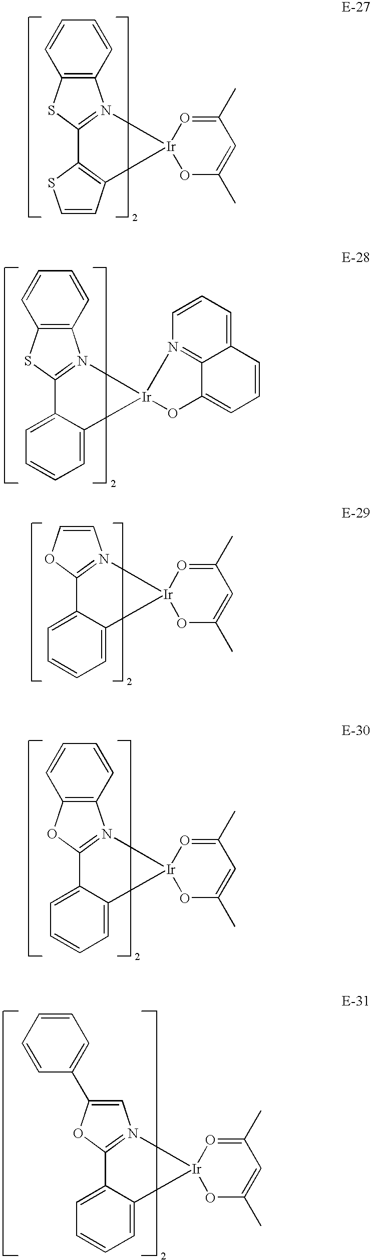

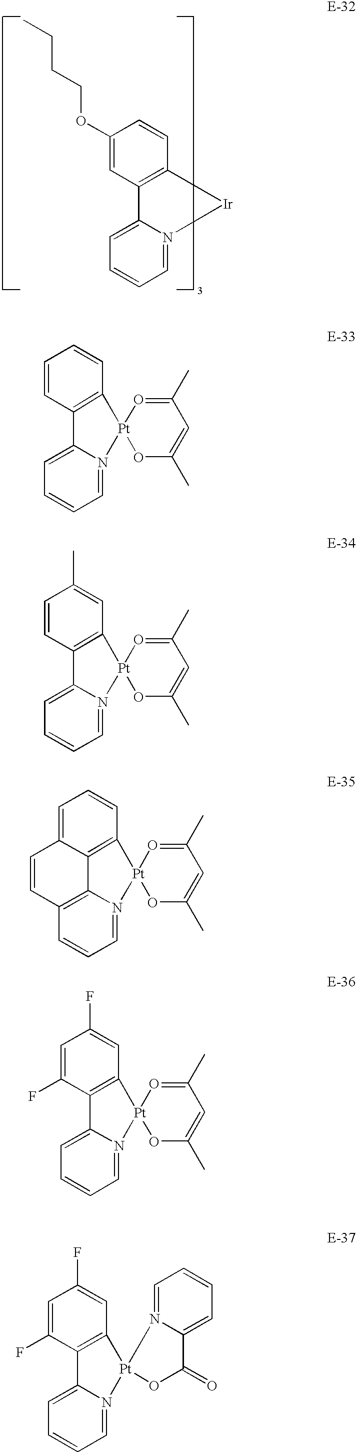

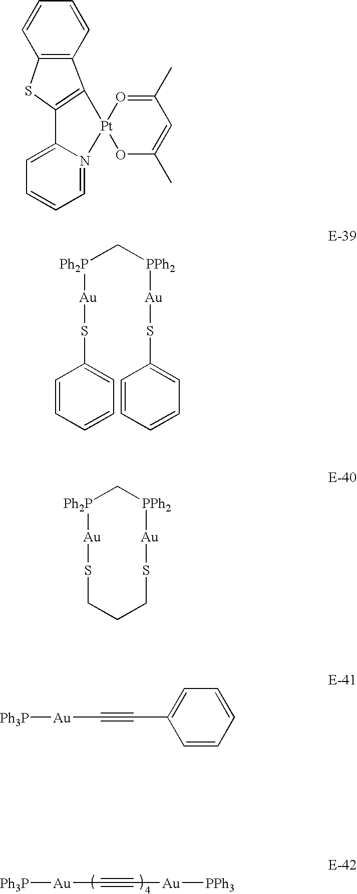

In the foregoing formulae, Ph represents a phenyl group.

Examples of the substituent in these phosphorescent compounds include a vinyl group, an acrylate group, a methacrylate group, a urethane (meth)acrylate group such as a methacryloyloxyethyl carbamate group, a styryl group and derivatives thereof, and a vinylamide group and derivatives thereof. Of these, a vinyl group, a methacrylate group, and a styryl group and derivatives thereof are preferable. Such a substituent may be bound to the metal complex via an organic group having from 1 to 20 carbon atoms, which may contain a heteroatom.

As the polymerizable substituent-containing carrier transport compound, compounds resulting from substituting at least one hydrogen atom of an organic compound having either one or both of hole transport properties and electron transport properties with a polymerizable substituent. Representative examples of such a compound include compounds represented by the following formulae (E-43) to (E-60).

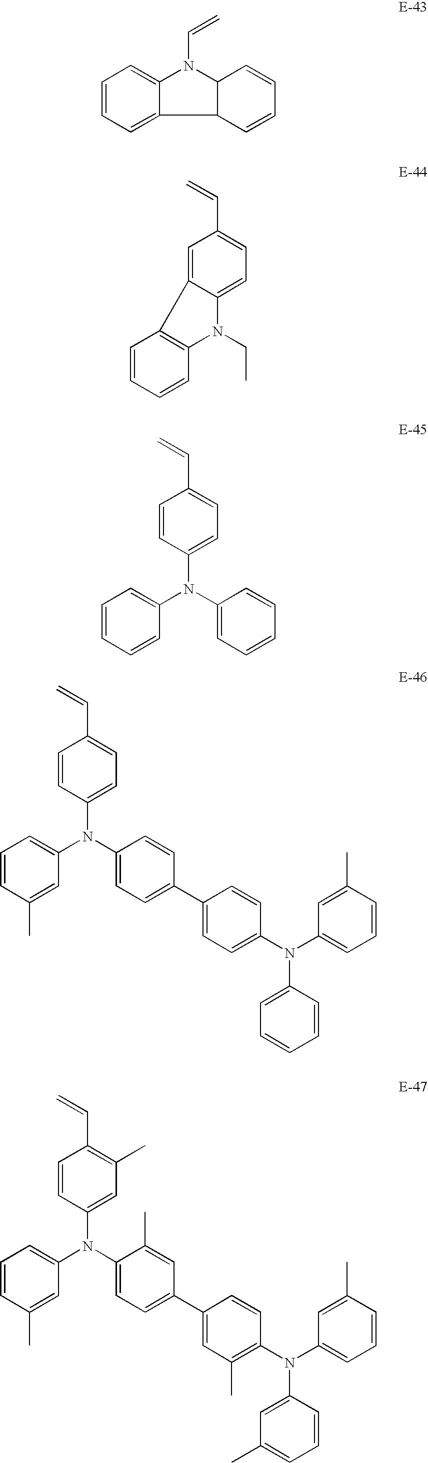

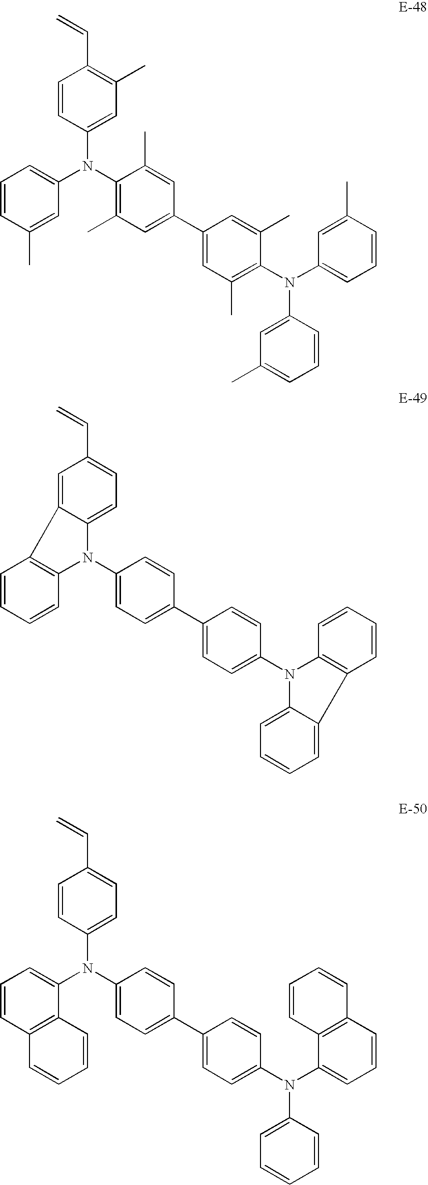

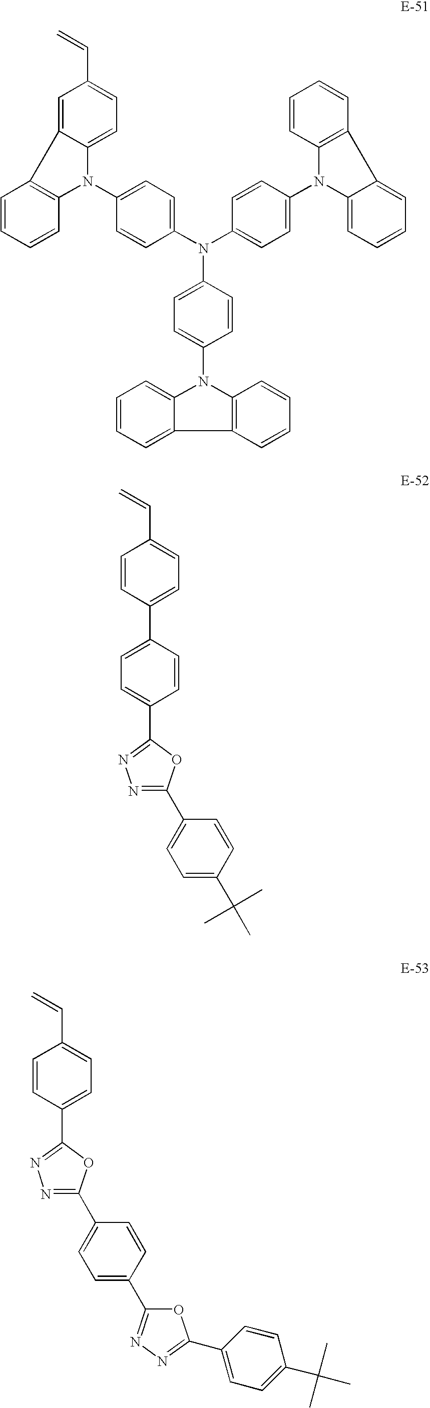

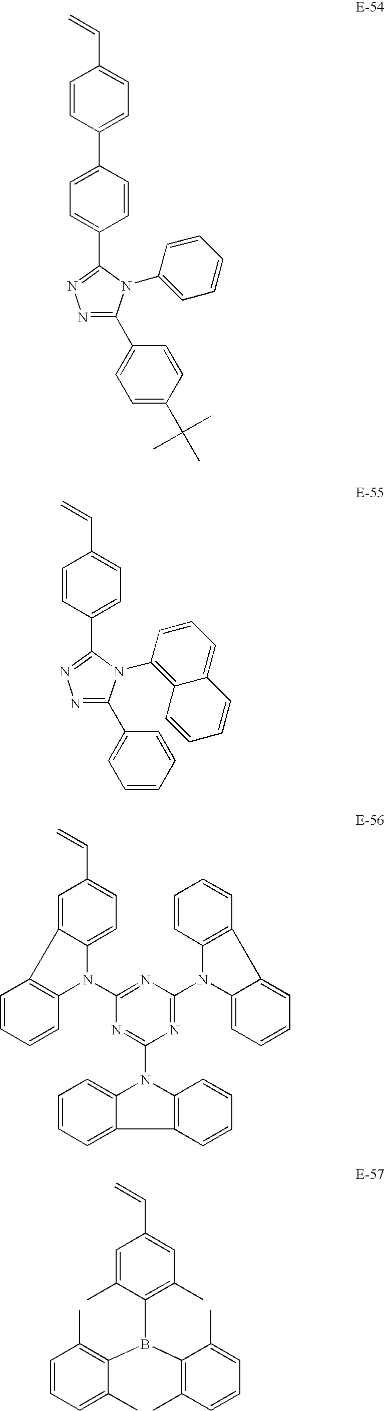

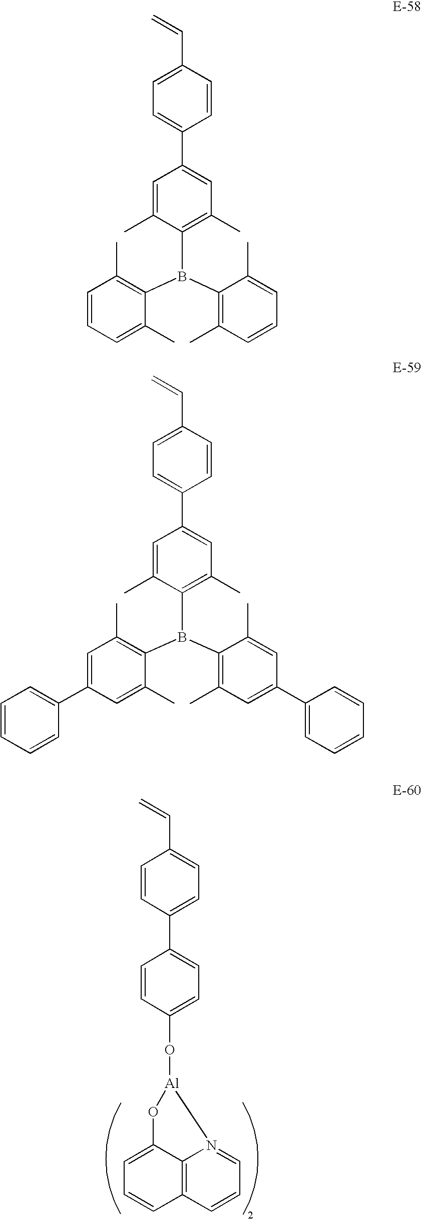

Though the polymerizable substituent in these enumerated carrier transport compounds is a vinyl group, compounds resulting from substituting the vinyl group with a polymerizable substituent such as an acrylate group, a methacrylate group, a urethane (meth)acrylate group such as a methacryloyloxyethyl carbamate group, a styryl group and derivatives thereof, and a vinylamide group and derivatives thereof may also be employed. Such a substituent may be bound via an organic group having from 1 to 20 carbon atoms, which may contain a hetero atom.

As a method for polymerizing the polymerizable substituent-containing phosphorescent compound and the polymerizable substituent-containing carrier transport compound, all of radical polymerization, cationic polymerization, anionic polymerization and addition polymerization are employable. Of these, radical polymerization is preferable. The molecular weight of the polymer is preferably from 1,000 to 2,000,000, and more preferably from 5,000 to 1,000,000 in terms of weight average molecular weight. The molecular weight as referred to herein is a molecular weight as reduced into polystyrene as measured using a GPC (gel permeation chromatography) method.

The phosphorescent high molecular compound may be a copolymer of one phosphorescent compound and one carrier transport compound, a copolymer of one phosphorescent compound and two or more carrier transport compounds, or a copolymer of two or more phosphorescent compounds and a carrier transport compound.

With respect to the configuration of monomers in the phosphorescent high molecular compound, all of random copolymers, block copolymers and alternate copolymers are useful. When the number of a repeating unit of the phosphorescent light-emitting compound structure is designated as “m” and the number of a repeating unit of the carrier transport compound structure is designated as “n” (m and n are each an integer of 1 or more), a proportion of the number of a repeating unit of the phosphorescent light-emitting compound structure to the total number of repeating units, namely a value of {m/(m+n)} is preferably from 0.001 to 0.5, and more preferably from 0.001 to 0.2.

More specific examples and synthesis methods of the phosphorescent high molecular compound are disclosed in, for example, JP-A-2003-342325, JP-A-2003-119179, JP-A-2003-113246, JP-A-2003-206320, JP-A-2003-147021, JP-A-2003-171391, JP-A-2004-346312, and JP-A-2005-97589.

In the organic light-emitting element of the invention, though the light-emitting layer is a layer containing the foregoing phosphorescent high molecular compound, it may contain a hole transport material or an electron transport material for the purpose of compensating the carrier transport properties of the light-emitting layer. Examples of the hole transport material which is used for such a purpose include low molecular triphenylamine derivatives such as TPD (N,N′-dimethyl-N,N′-(3-methylphenyl)-1,1′-biphenyl-4,4′diamine), α-NPD (4,4′-bis[N-(1-naphthyl)-N-phenylamino]biphenyl), and m-MTDATA (4,4′,4″-tris(3-methylphenylphenylamino)triphenylamine); polyvinylcarbazole; high molecular compounds resulting from introduction of a polymerizable functional group into the foregoing triphenylamine derivatives; high molecular compounds having a triphenylamine skeleton as disclosed in, for example, JP-A-8-157575; poly-p-phenylenevinylene; and polydialkylfluorenes. As the electron transport material, for example, low molecular compounds such as quinolinol derivative metal complexes such as Alq3 (aluminum trisquinolilate), oxadiazole derivatives, triazole derivatives, imidazole derivatives, triazine derivatives, and triarylborane derivatives; high molecular compounds resulting from introduction of a polymerizable functional group into the foregoing low molecular electron transport compounds; and already known electron transport materials such as poly-PBD as disclosed in, for example, JP-A-10-1665 can be used.

The foregoing light-emitting layer, hole-transporting layer and electron-transporting layer can be formed by a coating method such as a resistance heating vapor deposition method, an electron beam vapor deposition method, a sputtering method, a spin coating method, a casting method, a micro gravure coating method, a gravure coating method, a bar coating method, a roll coating method, a wire bar coating method, a dip coating method, a spray coating method, a screen printing method, a flexographic method, an offset printing method, and an inkjet printing method. In the case of a low molecular compound, a resistance heating vapor deposition method and an electron beam vapor deposition method are mainly employed; and in the case of a high molecular compound, a coating method such as a spin coating method, a casting method, a micro gravure coating method, a gravure coating method, a bar coating method, a roll coating method, a wire bar coating method, a dip coating method, a spray coating method, a screen printing method, a flexographic method, an offset printing method, and an inkjet printing method is mainly employed.

For the purposes of suppressing passage of a hole through the light-emitting layer and efficiently recombining it with an electron within the light-emitting layer, a hole block layer may be provided adjacent to the cathode side of the light-emitting layer. For this hole block layer, a compound having a highest occupied molecular orbital (HOMO) level deeper than that of the light-emitting material can be used. Examples thereof include triazole derivatives, oxadiazole derivatives, phenanthroline derivatives, and aluminum complexes.

In addition, for the purpose of preventing deactivation of the exciton by the cathode metal, an exciton block layer may be provided adjacent to the cathode side of the light-emitting layer. For this exciton block layer, a compound having excitation triplet energy larger than that of the light-emitting material can be used. Examples thereof include triazole derivatives, phenanthroline derivatives, and aluminum complexes.

### <<Cathode>>

As the cathode material of the organic light-emitting element of the invention, a cathode material which has a low work function and is chemically stable is useful. Examples thereof include already known cathode materials such as Al, MgAg alloys, and alloys of Al and an alkali metal or the like such as AlLi and AlCa. In the invention, AlLi is desirable as a first cathode, and Al is desirable as a second cathode. Examples of a film formation method of the cathode material which can be employed include a resistance heating vapor deposition method, an electron beam vapor deposition method, a sputtering method, and an ion plating method. A thickness of the cathode is preferably from 10 nm to 1 μm, and more preferably from 50 to 200 nm. Incidentally, in the case where the cathode is composed of a cathode made of plural layers, the “thickness (film thickness) of the cathode” as referred to in this specification means the total sum of the thicknesses (film thickness) of the respective cathode layers.

As the substrate of the organic light-emitting element according to the invention, already known materials which are an insulating substrate transparent to the luminescence wavelength of the light-emitting material, for example, glass, transparent plastics inclusive of PET (polyethylene terephthalate) and polycarbonate, and silicon substrates can be used.

In order to obtain surface light emission using the organic light-emitting element of the invention, a configuration may be taken such that surface anode and cathode overlay each other. In order to obtain pattern-like light emission, there are employable a method in which a mask having a pattern-like window is set up on the surface of the foregoing surface light-emitting element; a method in which an organic layer of a non-light-emitting area is formed extremely thick so that it becomes substantially non-light-emitting; and a method in which either one or both of an anode and a cathode are formed in a pattern-like state. When a pattern is formed by any one of these methods and some electrodes are configured such that they can be independently subjected to ON/OFF control, a display element of a segment type capable of displaying numerals, characters, simple symbols, or the like is obtained. In addition, in order to form a dot matrix element, both an anode and a cathode may be formed in a striped form and configured such that they are orthogonal to each other. It becomes possible to realize partial color display or multi-color display by a method of separately painting plural kinds of light-emitting materials having a different luminescent color or a method of using a color filter or a fluorescent conversion filter. The dot matrix element can be subjected to passive drive and may be subjected to active drive in combination with TFT, etc. Such a display element can be used as a display device in, for example, a computer, a television set, a portable terminal, a mobile phone, a car navigation system, and a view finder of video camera.

In addition, the foregoing surface light-emitting element is of a thin self light-emitting type and can be suitably used as a surface light source for backlight of liquid crystal display device or a light source for surface illumination. Also, by using a flexible substrate, it can be used as a curved surface light source or display device.

### EXAMPLES

The invention will be hereunder described in more detail with reference to the following Example and Comparative Example, but it should not be construed that the invention is limited to these descriptions.

For the sake of simplification, materials and layers formed therefrom will be abbreviated as follows.

ITO: Indium tin oxide (anode)

ELP: Fluorescent high molecular compound (copolymer of a three-component system containing a molecular structure of an aromatic amine (hole transport material segment), a boron based molecule (electron transport material segment) and an iridium complex (fluorescent dye segment); poly[viTPD-viTMB-viIr(ppy)₂(acac)])

### Example 1

### Preparation of Organic Light-Emitting Element

On one surface of a 25 mm-square glass substrate, an organic light-emitting element was prepared using an ITO (indium tin oxide)-provided substrate in which two ITO electrodes having a width of 4 mm were formed in a striped state as an anode. First of all, the anode substrate was washed with a liquid. That is, the anode substrate was washed with a commercially available detergent applying an ultrasonic wave and then subjected to running water washing with ultra-pure water. Thereafter, the anode substrate was dipped in and washed with isopropyl alcohol (IPA) applying an ultrasonic wave, followed by drying. In addition, the anode substrate was irradiated with UV ozone for 3 minutes, thereby decomposing the organic material remaining on the surface thereof.

Next, a coating solution for forming a light-emitting compound layer was prepared. That is, 60 mg of ELP was dissolved in 1,940 mg of toluene (special grade, manufactured by Wako Pure Chemical Industries, Ltd.), and the resulting solution was filtered through a filter having a pore size of 0.2 μm to prepare a coating solution. Next, the prepared coating solution was coated on the interlayer (ITO) by a spin coating method under conditions at a revolution number of 3,000 rpm for a coating time of 30 seconds and dried at 100° C. for 30 minutes to form a light-emitting layer. The resulting light-emitting layer had a thickness of about 90 nm. Next, the substrate having the light-emitting layer formed thereon was placed in a vacuum vapor deposition unit and vapor deposited with AlLi in a thickness of 10 nm at a vapor deposition rate of 0.01 nm/s. Subsequently, aluminum as a cathode was vapor deposited in a thickness of 150 nm at a vapor deposition rate of 1 nm/s to prepare an element 1. Incidentally, the layers of AlLi and aluminum were formed in a state of two stripes in a width of 3 mm orthogonal to the extending direction of the anode, thereby preparing four organic light-emitting elements of 4 mm in length×3 mm in width per glass substrate. This element was designated as an organic EL light-emitting element.

### Sealing and Evaluation

Cobalt stearate, a hydrogenated styrene-butadiene rubber (a trade name: DYNARON 132OP, manufactured by JSR Corporation; hereinafter abbreviated as “HSBR”) and polypropylene (a trade name: NOVATEC PP-FG3DF”, manufactured by Japan Polychem Corporation) were mixed in a weight ratio of 0.4/29.9/69.7 and kneaded in the presence of air at 210° C. using a roller mixer (R60, manufactured by Toyo Seiki Co., Ltd.) to prepare an oxygen absorbing resin composition (content of metal catalyst in resin: 428 ppm). Radicals in the prepared oxygen absorbing resin composition pellet were measured at room temperature using an electron spin resonance spectrometer (JES-FA200, manufactured by JEOL Ltd.; hereinafter referred to as “ESR”). 0.16 g of the sample pellet was charged in a sample tube having a diameter of 4 mm and measured at room temperature using manganese dioxide having an already known concentration of radical as a standard substance while setting up a magnetic center for observation at 336 mT. As a result, a spectrum having a g value of 2.004 to 2.005 was detected. It was confirmed from this intensity that 1.6×10⁻⁶ moles (namely 1.6×10⁻⁶×6×10²³ (spins)) of oxygen-containing organic radicals were present in one gram of the oxygen absorbing resin composition. Furthermore, a sample which had been stored in an oxygen-free state at 25° C. for 4 months exhibited the same electron spin resonance spectrum, and it was confirmed that these radicals were stably present over a long period of time. Next, the sample was press molded at 180° C. using a hot press machine to obtain a transparent oxygen absorbing film A having an average thickness of 114 μm.

The resulting oxygen absorbing film was cut out into a size of 5 cm×6 cm (0.34 g), which was then charged in an oxygen-impermeable bag together with 200 mL of dry air and a commercially available calcium oxide drying agent and sealed hermetically, followed by keeping at 25° C. The concentration of oxygen within the bag was measured and determined by a gas chromatograph. This oxygen absorbing film included an induction period of one day during which it did not substantially absorb oxygen and thereafter, absorbed oxygen at a fixed oxygen absorbing rate of 3.0 mL/g/day on the basis of the weight of the film.

This oxygen absorbing film A was fixed onto the internal surface of a glass-made sealing cap using an epoxy adhesive, and an ultraviolet light curable adhesive was coated on the periphery of the sealing cap. The sample was then set up in a glove box adjacent to the foregoing vacuum vapor deposition unit, and the inside of the glove box was rendered in an atmosphere containing 1,000 ppm of oxygen. The organic EL light-emitting element was delivered into the glove box from the vacuum vapor deposition unit. The organic EL light-emitting element and the adhesive-coated surface of the sealing cap were brought into intimate contact with each other and adhered to each other upon irradiation with ultraviolet light to seal the organic EL light-emitting element, thereby obtaining an organic EL light-emitting device. The organic EL light-emitting element was taken out into the air, 1 mA/cm² of a direct current was made to flow for 10 seconds, and the current was then shut off. In addition, after allowing the element to stand for 50 hours, characteristics of the element were examined.

That is, the foregoing organic EL element was subjected to constant current continuous drive at room temperature for 200 hours using the ITO film as an anode and AlLi/Al as a cathode while continuously applying a direct current such that the current density was 10 mA/cm², and the surface of the element was then enlarged 50 times and observed. As a result, anything unusual such as the generation of dark spots as a defective part was not observed at all.

### Comparative Example 1

An organic light-emitting element was prepared in the same manner as in Example 1. The oxygen absorbing film A as prepared in Example 1 was fixed onto the internal surface of a glass-made sealing cap using an epoxy adhesive within a glove box adjacent to the foregoing vacuum vapor deposition unit, and an ultraviolet light curable adhesive was coated on the periphery of the sealing cap. Thereafter, the inside of the glove box was rendered in an atmosphere containing 50 ppm of oxygen. The organic EL light-emitting element was delivered into the glove box from the vacuum vapor deposition unit. The organic EL light-emitting element and the adhesive-coated surface of the sealing cap were brought into intimate contact with each other and adhered to each other upon irradiation with ultraviolet light to seal the organic EL light-emitting element, thereby obtaining an organic EL light-emitting device.

The organic EL light-emitting element was taken out into the air, 1 mA/cm² of a direct current was made to flow for 10 seconds, and the current was then shut off. In addition, after allowing the element to stand for 50 hours, a rectification characteristic of the element was examined.

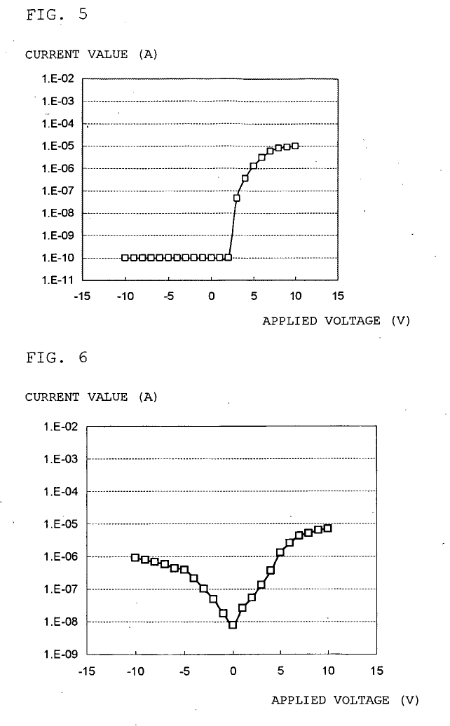

The rectification characteristic of each of the organic EL light-emitting devices as produced in Example 1 and Comparative Example 1 was examined using a semiconductor parameter analyzer. The measurement was carried out by applying a forward direction voltage and a reverse direction voltage between the anode ITO and the cathode Al of the organic EL light-emitting device. FIG. 5 shows a rectification characteristic of the organic EL light-emitting device as obtained by the foregoing measurement. Light having an irradiation wavelength of 400 nm was irradiated. The ordinate represents a current value; and the abscissa represents an applied voltage. The organic EL light-emitting device as prepared in Example 1 exhibited an excellent rectification characteristic as compared with the Comparative Example (FIG. 6).

1. An organic electro-luminescence light-emitting device having an organic light-emitting element comprising a transparent substrate having a transparent electrode (anode), a light-emitting compound layer containing a light-emitting compound and a cathode laminated thereon, and a sealing member for sealing the light-emitting element and shielding external air and an oxygen absorbing member, wherein oxygen is contained at an interface between the light-emitting compound layer and the cathode.

2. An organic electro-luminescence light-emitting device having an organic light-emitting element comprising a transparent substrate having a transparent electrode (anode), a light-emitting compound layer containing a light-emitting compound and a cathode laminated thereon, and a sealing member for sealing the light-emitting element and shielding external air and an oxygen absorbing member, wherein the cathode comprises a first cathode and a second cathode, and oxygen is contained at an interface between the light-emitting compound layer and the first cathode.

3. The organic electro-luminescence light-emitting device according to claim 2, wherein the first cathode and the second cathode are laminated.

4. An organic electro-luminescence light-emitting device having an organic light-emitting element comprising a transparent substrate having a transparent electrode (anode), a light-emitting compound layer containing a light-emitting compound and a cathode laminated thereon, and a sealing member for sealing the light-emitting element and shielding external air and an oxygen absorbing member, wherein the cathode comprises plural layers, and the content of oxygen in a first cathode of the plural cathodes, said first cathode coming into contact with the light-emitting compound layer, is higher than the content of oxygen in a cathode on and after the second cathode not coming into contact with the light-emitting compound layer.

5. The organic electro-luminescence light-emitting device according to claim 1, wherein the cathode has a film thickness of from 20 to 200 nm.

6. The organic electro-luminescence light-emitting device having an organic light-emitting element comprising a transparent substrate having a transparent electrode (anode), a light-emitting compound layer containing a light-emitting compound and a cathode laminated thereon, and a sealing member for sealing the light-emitting element and shielding external air and an oxygen absorbing member according to claim 1, wherein an oxygen absorbing member is present in a gap between the sealing member and the organic light-emitting element.

7. A process for producing an organic electro-luminescence light-emitting device as described in claim 1, which comprises forming the cathode in a film thickness of from 20 to 200 nm.

8. A process for producing an organic electro-luminescence light-emitting device having an organic light-emitting element comprising a transparent substrate having a transparent electrode (anode), a light-emitting compound layer containing a light-emitting compound and a cathode laminated thereon, and a sealing member for sealing the light-emitting element and shielding external air and an oxygen absorbing member as described in claim 6, wherein oxygen of a prescribed concentration is incorporated into the organic light-emitting device at the time of sealing.

9. A process for producing an organic electro-luminescence light-emitting device as described in claim 1, wherein the concentration of oxygen in the organic electro-luminescence light-emitting device at the time of sealing falls within the range of from 1,000 to 5,000 ppm, and the concentration of oxygen in the organic light-emitting device after from 10 to 50 hours after sealing is not more than 100 ppm.

10. The process for producing an organic electro-luminescence light-emitting device according to claim 9, wherein the oxygen absorbing member which absorbs oxygen in the organic electro-luminescence light-emitting device at the time of sealing starts to absorb oxygen step by step after sealing, thereby regulating the concentration of oxygen in the organic electro-luminescence light-emitting device at not more than 100 ppm within 50 hours.

11. The process for producing an organic electro-luminescence light-emitting device according to claim 10, wherein the light-emitting compound layer contains a phosphorescent high molecular material.

12. The process for producing an organic electro-luminescence light-emitting device according to claim 10, wherein the light-emitting compound layer contains a fluorescent high molecular material.

13. An organic electro-luminescence light-emitting device as produced by a production process as described in claim 7.

14. A surface emitting light source, a backlight for display devices, a display device, an illumination device, an interior or an exterior using an organic electro-luminescence light-emitting device as described in claim 1.

15. The organic electro-luminescence light-emitting device according to claim 2, wherein the cathode has a film thickness of from 20 to 200 nm.

16. The organic electro-luminescence light-emitting device according to claim 4, wherein the cathode has a film thickness of from 20 to 200 nm.
